(19) United States
(12) Patent Application Publication
(10) Pub. No.: US 2023/0072452 A1
(43) Pub. Date: Mar. 9, 2023

(54) SEMICONDUCTOR LASER ELEMENT

(71) Applicant: Panasonic Holdings Corporation, Osaka (JP)

(72) Inventors: ATSUNORI MOCHIDA, Osaka (JP); SHINICHIRO NOZAKI, Osaka (JP); MASANORI ERA, Kumamoto (JP)

(21) Appl. No.: 17/904,385

(22) PCT Filed: Mar. 2, 2021
(86) PCT No.: PCT/JP2021/007842

§ 371 Date: Aug. 17, 2022

(30) Foreign Application Priority Data
Mar. 17, 2020 (JP) 2020-046662

(51) Int. Cl. H01S 5/183; H01S 5/22; H01S 5/32

(52) U.S. Cl. CPC H01S 5/18369; H01S 5/222; H01S 5/3216; H01S 5/18377

(57) ABSTRACT

A reflectivity of an end surface protective film of a semiconductor laser element is made less than or equal to 1% in a wide wavelength range. Semiconductor laser element includes semiconductor stack body having front end surface and rear end surface, and end surface protective film disposed on front end surface of semiconductor stack body. End surface protective film includes first dielectric layer disposed on front end surface and second dielectric layer stacked outside first dielectric layer. Second dielectric layer includes first layer stacked on first dielectric layer, second layer stacked on first layer, and third layer stacked on second layer. For wavelength λ, of a laser beam, refractive index n2 of second layer is higher than refractive index n1 of first layer and refractive index n3 of third layer, and a film thickness of second layer ranges from λ(8n2) to 3λ(4n2) inclusive.

### TECHNICAL FIELD

The present disclosure relates to a semiconductor laser device.

### BACKGROUND ART

Conventionally, laser processing has been put to practical use. In order to expand the application of laser processing, a laser beam is required to have higher output power.

As one method for achieving higher output power and a narrower beam of a laser beam, a method using a semiconductor laser device (i.e., a laser array) having a plurality of luminous points as its light source has been proposed. In this method, a synthesis optical system that synthesizes a plurality of laser beams from the semiconductor laser device is constructed, and an external resonator is formed by the semiconductor laser device and a mirror disposed apart from the semiconductor laser device. By disposing the synthesis optical system in such an external resonator, a laser device that emits a laser beam having higher output power and a high beam quality can be achieved.

In the semiconductor laser device used in such a laser device of an external resonator type, it is required to reduce a reflectivity of a front end surface (main end surface for emitting laser beams) of the semiconductor laser device as much as possible in order to suppress resonance (i.e., internal resonance) of the laser beam inside the semiconductor laser device. The reflectivity is required to be, for example, less than or equal to 1%.

Examples of the method for synthesizing a plurality of laser beams include a spatial synthesis method for spatially synthesizing a plurality of laser beams and a wavelength synthesis method for focusing a plurality of laser beams having different wavelengths from each other on the same optical axis. In order to achieve a narrow beam by synthesizing a plurality of laser beams, the wavelength synthesis method for focusing a plurality of laser beams on the same optical axis is more advantageous than the spatial synthesis method in which a plurality of optical axes are different from each other.

On the other hand, in order to achieve wavelength synthesis in the external resonator, it is necessary to generate a plurality of laser beams having different wavelengths by the semiconductor laser device. A plurality of laser beams having different wavelengths can be generated by, for example, utilizing a laser array as the semiconductor laser device. Furthermore, a plurality of laser arrays can also be used to generate many laser beams.

### CITATION LIST

### Patent Literature

PTL 1: Unexamined Japanese Patent Publication No. 2010-219436

### SUMMARY OF THE INVENTION

The reflectivity of the front end surface of such a laser array is required to be less than or equal to 1% in a plurality of different wavelengths. However, in literatures (PTL 1, etc.) describing conventional technologies, an end surface protective film, capable of reducing to less than or equal to 1% in a wide wavelength range more than or equal to 50 nm, has not been reported. Therefore, the same end surface protective film cannot be used for all the luminous points of the laser array.

The present disclosure solves such a problem, and provides a semiconductor laser device including an end surface protective film capable of achieving a reflectivity less than or equal to 1% in a wide wavelength range.

One aspect of the semiconductor laser device according to the present disclosure includes a semiconductor stack body. The semiconductor stack body has a front end surface and a rear end surface, and further includes an end surface protective film. The end surface protective film is formed on the front end surface of the semiconductor stack body. The end surface protective film includes a first dielectric layer disposed on the front end surface, and a second dielectric layer stacked outside the first dielectric layer. The second dielectric layer includes a first layer stacked on the first dielectric layer, a second layer stacked on the first layer, and a third layer stacked on the second layer. For wavelength λ, of a laser beam emitted from the semiconductor laser device, refractive index n2 of the second layer is higher than refractive index n1 of the first layer and refractive index n3 of the third layer. A film thickness of the second layer ranges from λ/(8n2) to 3λ/(4n2) inclusive.

The end surface protective film having such a configuration can achieve a reflectivity less than or equal to 1% in a wide wavelength range more than or equal to 50 nm. Therefore, when the semiconductor laser device according to the present disclosure is used, for example, in a semiconductor laser device of an external resonator type that performs wavelength synthesis, it is not necessary to change the configuration of the end surface protective film for each luminous point that emits a laser beam. Therefore, the configuration of the semiconductor laser device can be simplified. Accordingly, a manufacturing process of the semiconductor laser device can be simplified, so that the manufacturing of the semiconductor laser device can be stabilized, and the cost of the semiconductor laser device can be reduced.

In one aspect of the semiconductor laser device according to the present disclosure, the first dielectric layer may include at least one layer of a dielectric film including at least one of a nitride film and an oxynitride film.

As a result, oxygen diffusion from the outside of the end surface protective film to the semiconductor stack body can be reduced. Therefore, the front end surface of the semiconductor stack body can be suppressed from being deteriorated. Therefore, the semiconductor laser device can be operated for a long period of time.

In one aspect of the semiconductor laser device according to the present disclosure, the end surface protective film may include at least two layers of dielectric films including at least one of a nitride film and an oxynitride film.

As a result, oxygen diffusion from the outside of the end surface protective film to the semiconductor stack body can be further reduced. Therefore, the front end surface of the semiconductor stack body can be further suppressed from being deteriorated.

In one aspect of the semiconductor laser device according to the present disclosure, the first dielectric layer may include at least one of a SiN film, an AlN film, a SiON film, an AlON film, an Al₂O₃ film, and a SiO2 film.

In one aspect of the semiconductor laser device according to the present disclosure, each of the first layer and the third layer may include at least one of a SiO2 film and an Al₂O₃ film.

As a result, the first layer and the third layer each having a relatively low refractive index can be achieved.

In one aspect of the semiconductor laser device according to the present disclosure, the second layer may include at least one of an AlN film, an AlON film, a TiO₂ film, a Nb₂O₅ film, a ZrO₂ film, a Ta₂O₅ film, and a HfO₂ film.

As a result, the second layer having a relatively high refractive index can be achieved.

In one aspect of the semiconductor laser device according to the present disclosure, the reflectivity of the end surface protective film is preferably less than or equal to 1.0% in a wavelength range, more than or equal to 50 nm, including the wavelength of the laser beam.

As a result, when the semiconductor laser device according to the present disclosure is used, for example, in a semiconductor laser device of an external resonator type that performs wavelength synthesis, it is not necessary to change the configuration of the end surface protective film for each luminous point that emits a laser beam. Therefore, the configuration of the semiconductor laser device can be simplified. Accordingly, a manufacturing process of the semiconductor laser device can be simplified, so that the manufacturing of the semiconductor laser device can be stabilized, and the cost of the semiconductor laser device can be reduced.

In one aspect of the semiconductor laser device according to the present disclosure, the reflectivity of the end surface protective film is more preferably less than or equal to 0.5% in a wavelength range, more than or equal to 50 nm, including the wavelength of the laser beam.

As a result, when the semiconductor laser device according to the present disclosure is used, for example, in a semiconductor laser device of an external resonator type that performs wavelength synthesis, it is not necessary to change the configuration of the end surface protective film for each luminous point that emits a laser beam. Therefore, the configuration of the semiconductor laser device can be simplified. Accordingly, a manufacturing process of the semiconductor laser device can be simplified, so that the manufacturing of the semiconductor laser device can be stabilized, and the cost of the semiconductor laser device can be reduced.

In one aspect of the semiconductor laser device according to the present disclosure, the semiconductor stack body may be formed of a gallium nitride-based material.

As a result, a semiconductor laser device that emits a laser beam having a wavelength in a band ranging approximately from 390 nm to 530 nm inclusive, can be realized. Although the gallium nitride-based material can have a problem that it will be deteriorated due to oxygen diffusion from an end surface, the end surface protective film according to the present disclosure can reduce oxygen diffusion from the end surface. Therefore, the reliability of the semiconductor laser device can be enhanced.

In one aspect of the semiconductor laser device according to the present disclosure, the semiconductor stack body may be formed of a gallium arsenide-based material.

As a result, a semiconductor laser device that emits a laser beam having a wavelength in an infrared band ranging approximately from 750 nm to 1100 nm inclusive, can be achieved.

One aspect of the semiconductor laser device according to the present disclosure may include a plurality of luminous points, and each of the plurality of luminous points may emit a laser beam.

As a result, a small laser light source capable of emitting a plurality of laser beams can be achieved. By using such a semiconductor laser device in a semiconductor laser device of an external resonator type that performs wavelength synthesis, a small semiconductor laser device can be achieved.

According to the present disclosure, a semiconductor laser device, including an end surface protective film capable of achieving a reflectivity less than or equal to 1% in a wide wavelength range, can be provided.

### BRIEF DESCRIPTION OF THE DRAWINGS

FIG. 1 is a schematic cross-sectional view illustrating a configuration of a semiconductor laser device according to a first exemplary embodiment.

FIG. 2 is a graph showing reflectivity dependence on wavelength of an end surface protective film according to the first exemplary embodiment.

FIG. 3 is a graph showing reflectivity dependence on wavelength of a second dielectric layer of the end surface protective film according to the first exemplary embodiment.

FIG. 4 is a graph in which a part of FIG. 3 is enlarged.

FIG. 5 is a schematic plan view illustrating a configuration of a semiconductor laser device to which the semiconductor laser device according to the first exemplary embodiment is applied.

FIG. 6 is a schematic cross-sectional view illustrating a configuration of a semiconductor laser device according to a second exemplary embodiment.

FIG. 7 is a schematic cross-sectional view illustrating a configuration of a semiconductor laser device according to a third exemplary embodiment.

### DESCRIPTION OF EMBODIMENT

Hereinafter, exemplary embodiments of the present disclosure will be described with reference to the drawings. Note that each of the exemplary embodiments described below describes a specific example of the present disclosure. Therefore, numerical values, shapes, materials, components, placement positions and connection forms of the components, and the like shown in the following exemplary embodiments are merely examples, and are not intended to limit the present disclosure.

Each drawing is a schematic one and is not necessarily strictly illustrated. Therefore, scales and the like are not necessarily matched in the respective drawings. Note that, in each drawing, substantially the same components are denoted by the same reference marks, and redundant description will be omitted or simplified.

Furthermore, in the present description, the terms “upward” and “downward” do not refer to an upward direction (vertically upward) and a downward direction (vertically downward) in absolute space recognition, but are used as terms defined by a relative positional relationship based on a stacking order in a stacking configuration. Also, the terms “upward” and “downward” are applied not only when two components are disposed to be spaced apart from each other and there is another component between the two components, but also when two components are disposed in contact with each other.

### First Exemplary Embodiment

A semiconductor laser device according to a first exemplary embodiment will be described.

[1-1. Overall configuration]

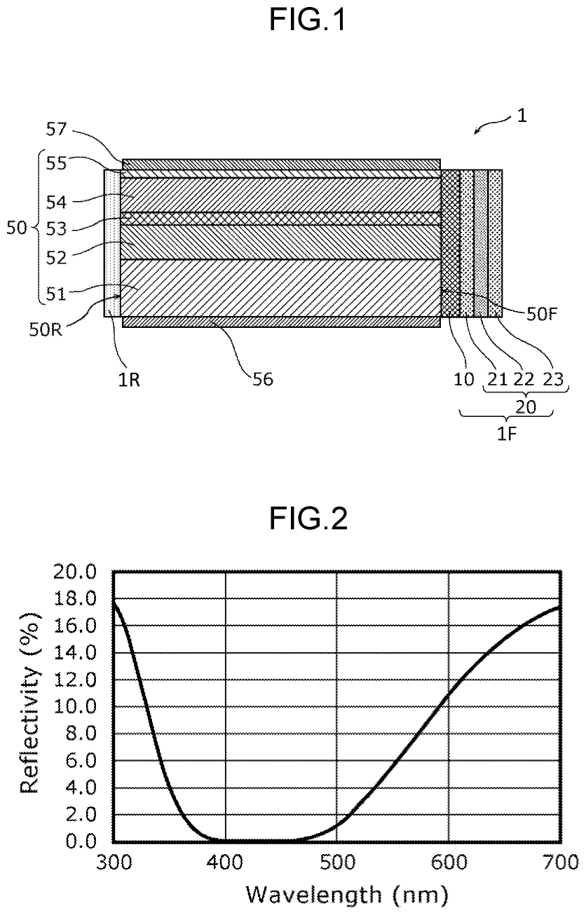

First, an overall configuration of a semiconductor laser device according to the present exemplary embodiment will be described with reference to FIG. 1. FIG. 1 is a schematic cross-sectional view illustrating a configuration of semiconductor laser device 1 according to the present exemplary embodiment. FIG. 1 illustrates a cross section along a stacking direction (vertical direction in FIG. 1) of semiconductor stack body 50 included in semiconductor laser device 1 and a resonance direction (horizontal direction in FIG. 1) of a laser beam.

Semiconductor laser device 1 is a semiconductor light emitting element that emits a laser beam. As illustrated in FIG. 1, semiconductor laser device 1 includes semiconductor stack body 50 and end surface protective film 1F. In the present exemplary embodiment, semiconductor laser device 1 further includes end surface protective film 1R, first electrode 56, and second electrode 57.

[1-1-1. Configurations of semiconductor stack body and electrode]

Semiconductor stack body 50 is a stack body in which a plurality of semiconductor layers constituting semiconductor laser device 1 are stacked. As illustrated in FIG. 1, semiconductor stack body 50 has front end surface 50F and rear end surface 50R that are end surfaces opposite to each other. End surface protective films 1F and 1R are disposed on front end surface 50F and rear end surface 50R, respectively.

Semiconductor stack body 50 includes substrate 51, first semiconductor layer 52, active layer 53, second semiconductor layer 54, and contact layer 55. In the present exemplary embodiment, semiconductor stack body 50 is formed of a gallium nitride-based material. As a result, semiconductor laser device 1 that emits a laser beam having a wavelength in a band ranging approximately from 390 nm to 530 nm inclusive, can be achieved.

Substrate 51 is a plate-shaped member serving as a base material of semiconductor stack body 50. In the present exemplary embodiment, substrate 51 is a GaN single crystal substrate having a thickness of 100 Note that the thickness of substrate 51 is not limited to 100 and may range, for example, from 50 μm to 120 μm inclusive. In addition, the material for forming substrate 51 is not limited to GaN single crystal, and may be sapphire, SiC, or the like.

First semiconductor layer 52 is a semiconductor layer of a first conductivity type disposed above substrate 51. In the present exemplary embodiment, first semiconductor layer 52 is an n-type semiconductor layer disposed on one principal surface of substrate 51, and includes an n-type clad layer. The n-type clad layer is a layer having a thickness of 1μm and containing n-Al_{0.2}Ga_{0.8}N. Note that the configuration of the n-type clad layer is not limited thereto. The thickness of the n-type clad layer may be more than or equal to 0.5 and the composition may be n-AlₓGa₁₋ₓN (0<x<1).

Active layer 53 is a luminous layer disposed above first semiconductor layer 52. In the present exemplary embodiment, active layer 53 is a quantum well active layer in which well layers each containing In_{0.18}Ga_{0.82}N and having a thickness of 5 nm and barrier layers each containing GaN and having a thickness of 10 nm are alternately stacked. Active layer 53 has two well layers. By providing such active layer 53, semiconductor laser device 1 can emit a blue laser beam having a wavelength of about 450 nm. The configuration of active layer 53 is not limited to this, and has only to be a quantum well active layer in which well layers each containing InₓGaᵢ₋ₓN (0<x<1) and barrier layers each containing AlₓIn_{y}Ga_{1-x-y}N (0≤x+y≤1) are alternately stacked. Note that active layer 53 may include a guide layer formed at least one of above and below the quantum well active layer. In the present exemplary embodiment, the number of the well layers is two, but it may range from one layer to four layers inclusive. In addition, the In composition of the well layer may be appropriately selected such that a beam having, of wavelengths ranging from 390 nm to 530 nm inclusive, a desired wavelength can be generated.

Second semiconductor layer 54 is a semiconductor layer of a second conductivity type disposed above active layer 53. The second conductivity type is a different conductivity type from the first conductivity type. In the present exemplary embodiment, second semiconductor layer 54 is a p-type semiconductor layer and includes a p-type clad layer. The p-type clad layer is a superlattice layer in which 100 layers each containing p-Al_{0.2}Ga_{0.8}N and having a thickness of 3 nm and 100 layers each containing GaN and having a thickness of 3 nm are alternately stacked. The configuration of the p-type clad layer is not limited thereto, and may include layers each containing AlₓGa₁₋ₓN (0<x<1) and having a thickness ranging from 0.3 μm to 1 μm inclusive.

Note that the p-type clad layer may be formed of a material other than AlGaN. The p-type clad layer may be formed of another material having a refractive index suitable for confining beams in active layer 53.

Contact layer 55 is a semiconductor layer of the second conductivity type that is in ohmic contact with second electrode 57. In the present exemplary embodiment, contact layer 55 is a p-type semiconductor layer, and is a layer having a thickness of 10 nm and containing p-GaN. Note that the configuration of contact layer 55 is not limited thereto. The thickness of contact layer 55 may be more than or equal to 5 nm.

In the present exemplary embodiment, one or more ridge portions are formed in second semiconductor layer 54 and contact layer 55. A region of active layer 53 corresponding to each ridge portion (i.e., a region of active layer 53 located below each ridge portion) serves as a luminous point that emits a laser beam.

First electrode 56 is an electrode disposed on a lower principal surface of substrate 51 (i.e., a principal surface on which first semiconductor layer 52 and the like are not disposed). In the present exemplary embodiment, first electrode 56 is a stack film in which Ti, Pt, and Au are sequentially stacked from substrate 51. The configuration of first electrode 56 is not limited thereto. First electrode 56 may be a stack film in which Ti and Au are stacked.

Second electrode 57 is an electrode disposed on contact layer 55. In the present exemplary embodiment, second electrode 57 includes a p-side electrode in ohmic contact with contact layer 55, and a pad electrode disposed on the p-side electrode.

The p-side electrode is a stack film in which Pd and Pt are sequentially stacked from contact layer 55. The configuration of the p-side electrode is not limited thereto. The p-side electrode may be a single-layer film or a multilayer film that is formed of, for example, at least one of Cr, Ti, Ni, Pd, Pt, and Au.

The pad electrode is a pad-shaped electrode disposed above the p-side electrode. In the present exemplary embodiment, the pad electrode is a stack film in which Ti and Au are sequentially stacked from the p-side electrode side. It is disposed in and around the ridge portion. The configuration of the pad electrode is not limited thereto. The pad electrode may be, for example, a stack film of Ti, Pt, and Au, a stack film of Ni and Au, or a stack film of other metals.

Although not illustrated in FIG. 1, semiconductor stack body 50 may further include an insulating film, such as a SiO₂ film, covering a side wall of the ridge portion, and the like in addition to the above layers.

[1-1-2. Configurations of end surface protective films IF and 1R]

End surface protective film IF is a protective film disposed on front end surface 50F of semiconductor stack body 50. End surface protective film IF protects front end surface 50F of semiconductor stack body 50 and reduces the reflectivity of front end surface 50F for a laser beam. End surface protective film IF includes first dielectric layer 10 and second dielectric layer 20.

First dielectric layer 10 is a dielectric layer disposed on front end surface 50F. First dielectric layer 10 may include at least one layer of a dielectric film including at least one of a nitride film and an oxynitride film. As a result, oxygen diffusion in the direction from front end surface 50F to semiconductor stack body 50 can be reduced. Therefore, the front end surface of the semiconductor stack body can be suppressed from being deteriorated. Therefore, the semiconductor laser device can be operated for a long period of time.

In addition, first dielectric layer 10 is directly connected to front end surface 50F of semiconductor stack body 50 (i.e., formed in contact with front end surface 50F). Therefore, by using, as first dielectric layer 10, a nitride film or an oxynitride film having crystallinity similar to that of semiconductor stack body 50, the protection performance for front end surface 50F can be enhanced. In the present exemplary embodiment, first dielectric layer 10 includes an AlON film. More specifically, first dielectric layer 10 is a single-layer film including an AlON film having a thickness of about 20 nm. Note that the configuration of first dielectric layer 10 is not limited thereto. First dielectric layer 10 may be another oxynitride film such as SiON, or a nitride film such as an AN film or a SiN film.

Second dielectric layer 20 is a dielectric layer stacked outside first dielectric layer 10. It includes first layer 21 stacked on the first dielectric layer, second layer 22 stacked on first layer 21, and third layer 23 stacked on second layer 22. For a laser beam having wavelength λ, that is emitted from semiconductor laser device 1, refractive index n2 of second layer 22 is higher than refractive index n1 of first layer 21 and refractive index n3 of third layer 23. The film thickness of second layer 22 ranges from λ/(8n2) to 3λ/(4n2) inclusive. As a result, end surface protective film 1F, having a reflectivity less than or equal to 1% in a wide wavelength range, can be achieved. Here, reflectivity dependence on wavelength of end surface protective film 1F will be described with reference to FIG. 2. FIG. 2 is a graph showing the reflectivity dependence on wavelength of end surface protective film 1F according to the present exemplary embodiment. FIG. 2 illustrates a graph obtained by calculation. The vertical axis and the horizontal axis in FIG. 2 represent a reflectivity and a wavelength, respectively. As illustrated in FIG. 2, the reflectivity of end surface protective film 1F is less than or equal to 1% in a wavelength range, more than or equal to 50 nm, including the wavelength of the laser beam. More specifically, the reflectivity of end surface protective film 1F is less than or equal to 0.5% in a wavelength range, more than or equal to 50 nm, including the wavelength of the laser beam. In the example illustrated in FIG. 2, a reflectivity less than or equal to 0.5% is obtained in a wavelength range, more than or equal to 100 nm, ranging approximately from 400 nm to 500 nm inclusive.

In the present exemplary embodiment, first layer 21 is an Al₂O₃film having a thickness of about 100 nm. First layer 21 has only to be a dielectric film having a lower refractive index than that of second layer 22, and may include, for example, at least one of a SiO2 film and an Al₂O₃film. As a result, first layer 21 having a relatively low refractive index can be achieved.

In the present exemplary embodiment, second layer 22 is a ZrO₂ film having a thickness of about 50 nm. Second layer 22 has only to be a dielectric film having a higher refractive index than those of first layer 21 and third layer 23. For example, when first layer 21 and third layer 23 are Al₂O₃films or SiO2 films, second layer 22 may include at least one of an AlN film, an AlON film, a TiO₂ film, a Nb₂O₅ film, a ZrO₂ film, a Ta₂O₅ film, and a HfO₂ film. In addition, second layer 22 may include at least one of a SiN film and a SiON film. As a result, second layer 22 having a relatively high refractive index can be achieved.

In the present exemplary embodiment, third layer 23 is a SiO2 film having a thickness of about 100 nm. Third layer 23 has only to be a dielectric film having a lower refractive index than that of second layer 22, and may include, for example, at least one of a SiO2 film and an Al₂O₃film. As a result, third layer 23 having a relatively low refractive index can be realized.

End surface protective film 1R is a protective film disposed on rear end surface 50R of semiconductor stack body 50. End surface protective film 1R protects rear end surface 50R of semiconductor stack body 50 and increases the reflectivity of rear end surface 50R for a laser beam. In the present exemplary embodiment, end surface protective film 1R is a multilayer film in which a plurality of pairs of SiO2 films and ZrO₂ films each having a thickness of about V(4n), where X, is the wavelength of the laser beam, are stacked. Here, n represents the refractive index of each dielectric film. As a result, the reflectivity of end surface protective film 1R for the laser beam can be made more than or equal to 90%. Note that the configuration of end surface protective film 1R is not limited thereto, and a configuration, as long as a desired reflectivity can be obtained with it, may be adopted in which a plurality of pairs of SiO2 films and Ta₂O₅ films, SiO2 films and AlON films, SiO₂ films and AlN films, SiO₂ films and TiO₂ films, SiO₂ films and HfO₂ films, SiO₂ films and Nb₂O₅ films, or the like are stacked. In addition, as the low refractive index films of the above pairs, Al₂O₃films may be used. Similarly to end surface protective film 1F, end surface protective film 1R may also include at least one of a nitride film and an oxynitride film.

[1-2. Action and effects of end surface protective film 1F]

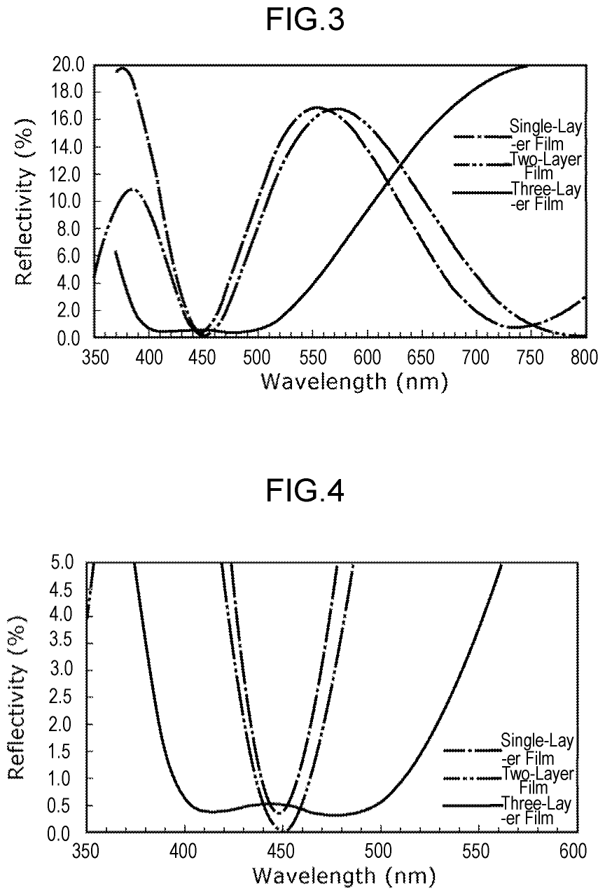

Next, an action and effects of end surface protective film 1F according to the present exemplary embodiment will be described with reference to FIG. 3 and FIG. 4 while comparing with those in a comparative example. FIG. 3 is a graph showing reflectivity dependence on wavelength of second dielectric layer 20 of end surface protective film 1F according to the present exemplary embodiment. FIG. 4 is a graph in which a part of FIG. 3 is enlarged. FIG. 3 and FIG. 4 illustrate graphs obtained by calculation. The vertical axis and the horizontal axis in each of FIG. 3 and FIG. 4 represent a reflectivity and a wavelength, respectively. Each of FIG. 3 and FIG. 4 also illustrates reflectivity dependence on wavelength of an end surface protective film of a comparative example. The solid line graph illustrated in each of FIG. 3 and FIG. 4 shows the reflectivity of second dielectric layer 20 including the three-layer film according to the present exemplary embodiment. The dashed line graph and the two-dot chain line graph illustrated in each of FIG. 3 and FIG. 4 show a reflectivity of a single-layer film of a first comparative example and a reflectance of a two-layer film of a second comparative example, respectively.

In the case of the single-layer film of the first comparative example, a low reflectivity of about 0.3% can be achieved, but a wavelength range in which a low reflectivity can be obtained is narrow, as illustrated in FIG. 3 and FIG. 4. Specifically, a wavelength range in which the reflectivity is less than or equal to 0.5% is about 10 nm, and a wavelength range in which the reflectivity is less than or equal to 1% is about 20 nm. In the case of the two-layer film of the second comparative example, a low reflectivity less than or equal to 0.1% can be achieved, but also in this case, a wavelength range in which a low reflectivity can be obtained is narrow, similarly to the first comparative example.

On the other hand, in the case of a three-layer film using, as second layer 22, a high refractive index film as in second dielectric layer 20 according to the present exemplary embodiment, reflectivity dependence on wavelength in a wavelength range of low reflectivity can be reduced, as illustrated in FIG. 4. Therefore, a low reflectivity can be achieved over a wide wavelength range. Therefore, when semiconductor laser device 1 according to the present exemplary embodiment is used, for example, in a semiconductor laser device of an external resonator type that performs wavelength synthesis, it is not necessary to change the configuration of the end surface protective film for each luminous point that emits a laser beam. Therefore, the configuration of the semiconductor laser device can be simplified. Accordingly, a manufacturing process of the semiconductor laser device can be simplified, so that the manufacturing of the semiconductor laser device can be stabilized, and the cost of the semiconductor laser device can be reduced.

Here, a reason why a wide range of low reflectivity can be achieved in second dielectric layer 20 according to the present exemplary embodiment will be described. In second dielectric layer 20 according to the present exemplary embodiment, two wavelengths close to 450 nm, among wavelengths at each of which a reflectivity takes a minimum value, can respectively be brought close to about 420 nm and about 480 nm by increasing an optical path length (i.e., an optical path length in the thickness direction of second dielectric layer 20) more than the single-layer film and the two-layer film. Here, the minimum value at a point where wavelength λ. is 420 nm is a minimum value generated when the optical path length in the thickness direction of second dielectric layer 20 becomes a multiple of λ/4, and the minimum value at a point where wavelength λ, is 480 nm is a minimum value generated when the optical path length in the thickness direction of second dielectric layer 20 becomes a multiple of λ/2.

Furthermore, in order to suppress a reflectivity at a wavelength between 420 nm and 480 nm, a high refractive index film is used as second layer 22.

By the above method, second dielectric layer 20 that can obtain a low reflectivity in a wide wavelength range can be achieved.

However, an end surface protective film that can be applied to a high output power semiconductor laser device cannot be achieved only by second dielectric layer 20 having the three-layer structure. The end surface protective film that can be applied to a high output power semiconductor laser device needs to be able to reduce destruction of front end surface 50F even in a long-term reliability test for the semiconductor laser device. Therefore, end surface protective film 1F according to the present exemplary embodiment includes first dielectric layer 10 disposed between second dielectric layer 20 and front end surface 50F. As a result, end surface protective film 1F can achieve both reliability and the reflectivity characteristics.

In the present exemplary embodiment, semiconductor stack body 50 is formed of a gallium nitride-based material.

As a result, semiconductor laser device 1 that emits a laser beam having a wavelength in a band ranging approximately from 390 nm to 530 nm inclusive, can be achieved. Although the gallium nitride-based material can have a problem that it will be deteriorated due to oxygen diffusion from an end surface, but end surface protective film 1F according to the present exemplary embodiment can reduce oxygen diffusion from front end surface 50F. Therefore, the reliability of semiconductor laser device 1 can be enhanced.

[1-3. Manufacturing method]

Next, a method for manufacturing semiconductor laser device 1 according to the present exemplary embodiment will be described.

First, semiconductor stack body 50 is formed. In forming semiconductor stack body 50, substrate 51 is first prepared, and first semiconductor layer 52, active layer 53, second semiconductor layer 54, and contact layer 55 are sequentially stacked. In the present exemplary embodiment, the n-type clad layer, active layer 53, the p-type clad layer, and contact layer 55 are sequentially stacked on substrate 51. Deposition of each layer can be performed, for example, by metal organic chemical vapor deposition (MOCVD).

Subsequently, the ridge portion is formed in second semiconductor layer 54 and contact layer 55. The ridge portion can be formed, for example, by inductive coupled plasma (ICP) type reactive ion etching or the like.

As described above, semiconductor stack body 50 of semiconductor laser device 1 can be formed.

Subsequently, an insulating film, such as a SiO₂ film, is formed, for example, by a plasma CVD method or the like. At least a part of an upper surface of the ridge portion of the insulating film is removed by wet etching or the like.

Subsequently, second electrode 57 is formed on the ridge portion by, for example, a vacuum deposition method or the like.

Subsequently, first electrode 56 is formed on a lower surface of substrate 51 by, for example, a vacuum deposition method or the like.

Next, end surface protective film 1F and end surface protective film 1R are formed on front end surface 50F and rear end surface 50R of semiconductor stack body 50, respectively. For respectively forming the dielectric films on front end surface 50F and rear end surface 50R, for example, a solid-source electron cyclotron resonance (ECR) sputtering plasma deposition apparatus is used. As a result, damage to each end surface, possibly occurring when each dielectric film is formed, can be suppressed.

As described above, semiconductor laser device 1 according to the present exemplary embodiment can be manufactured.

[1-4. Application example]

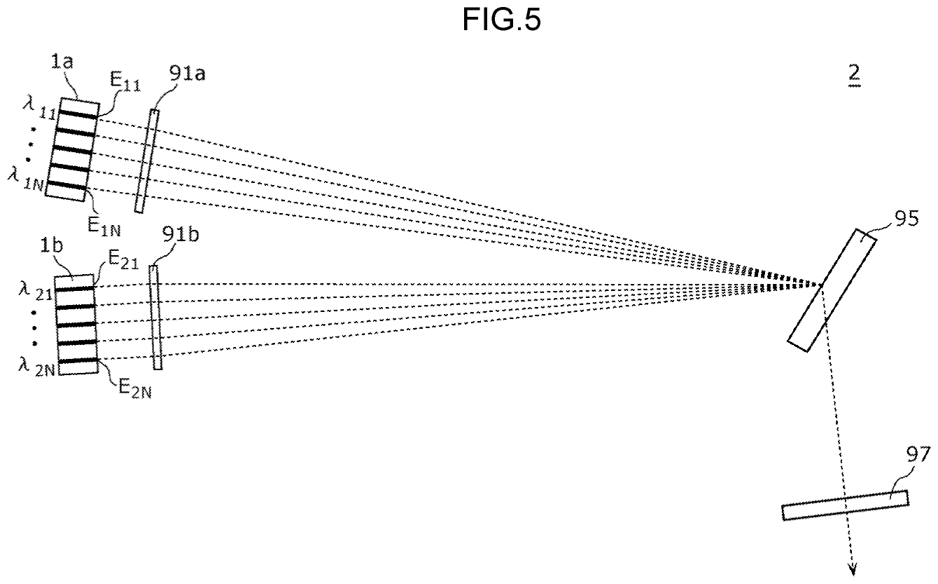

Next, an application example of semiconductor laser device 1 according to the present exemplary embodiment will be described. Semiconductor laser device 1 according to the present exemplary embodiment can be applied to, for example, a semiconductor laser device of an external resonator type that performs wavelength synthesis. Hereinafter, the semiconductor laser device to which semiconductor laser device 1 is applied will be described with reference to FIG. 5. FIG. 5 is a schematic plan view illustrating a configuration of semiconductor laser appatatus 2 to which semiconductor laser devicelaser device 1 according to the present exemplary embodiment is applied.

As illustrated in FIG. 5, semiconductor laser appatatus 2 includes semiconductor laser devicelaser devices la and lb, optical lenses 91a and 91b, diffraction grating 95, and partially reflective mirror 97.

Each of semiconductor laser devicelaser devices la and lb is an example of semiconductor laser devicelaser device 1 according to the present exemplary embodiment. Semiconductor laser devicelaser devices la and lb are laser arrays, and respectively have N (N is an integer more than or equal to 2) luminous points E₁₁ to E_{1N} and N luminous points E₂₁ to E_{2N}. Each of these luminous points emits a laser beam. The wavelength of the laser beam emitted from each luminous point is determined by a wavelength selection action by an external resonator including diffraction grating 95 to be described later. In semiconductor laser devicelaser device 1a, luminous points E₁₁ to E_{1N} respectively emit laser beams having wavelengths λ₁₁ to λ_{1N} different from each other. In semiconductor laser devicelaser device 1b, luminous points E₂₁ to E_{2N} respectively emit laser beams having wavelengths λ₂₁ to λ2N different from each other. Semiconductor laser devicelaser devices la and lb are disposed such that the respective laser beams propagate in the same plane.

Optical lenses 91a and 91b are optical elements that respectively focus the laser beams emitted from semiconductor laser devicelaser devices la and lb onto diffraction grating 95. Note that each of optical lenses 91a and 91b may have a function of collimating each laser beam. In addition, semiconductor laser appatatus 2 may include a collimating lens that collimates each laser beam, separately from optical lenses 91a and 91b.

Diffraction grating 95 is a wavelength dispersion element that multiplexes a plurality of laser beams having different wavelengths from each other. By appropriately setting the wavelengths and incident angles of a plurality of laser beams to be incident on diffraction grating 95 and intervals between slits of diffraction grating 95, the plurality of laser beams in different propagation directions can be synthesized on substantially the same optical axis.

Partially reflective mirror 97 is a mirror that forms an external resonator with the rear end surface of each semiconductor laser devicelaser device, and functions as an output coupler that emits a laser beam. A reflectivity and a transmittance of partially reflective mirror 97 may be appropriately set according to the gain or the like of each semiconductor laser devicelaser device.

Operations of semiconductor laser appatatus 2 having the above configuration will be described. Each of semiconductor laser devicelaser devices la and lb emits N laser beams when a current is supplied. The N laser beams emitted from semiconductor laser devicelaser device la are focused on a focal point on diffraction grating 95 by optical lens 91a, while the N laser beams emitted from semiconductor laser devicelaser device lb are focused on the focal point on diffraction grating 95 by optical lens 91b. Each laser beam transmitted through diffraction grating 95 is diffracted by diffraction grating 95, propagates on substantially the same optical axis, and travels toward partially reflective mirror 97. A part of each laser beam traveling toward partially reflective mirror 97 is reflected by partially reflective mirror 97, and returns to the semiconductor laser devicelaser device that has emitted the laser beam via diffraction grating 95 and optical lens 91a or 91b. As described above, the external resonator is formed between rear end surface 50R of each semiconductor laser devicelaser device and partially reflective mirror 97. On the other hand, the laser beam transmitted through partially reflective mirror 97 becomes an output beam of semiconductor laser appatatus 2, whereby a high output power laser beam can be obtained, for example, by an optical fiber or the like disposed on the optical axis of the output beam.

When the external resonator is formed by utilizing partially reflective mirror 97, it is necessary to suppress internal resonance in each semiconductor laser devicelaser device. In order to suppress internal resonance in each semiconductor laser devicelaser device, it is necessary to reduce as much as possible reflection of a beam on front end surface 50F of each semiconductor laser devicelaser device. Therefore, it is necessary to reduce the reflectivity of end surface protective film 1F disposed on front end surface 50F to less than or equal to 1%. Note that the reflectivity of end surface protective film 1F is more preferably less than or equal to 0.5%. As a result, internal resonance in each semiconductor laser devicelaser device can be further suppressed.

Examples of the method for synthesizing beams include a wavelength synthesis method to be used in semiconductor laser appatatus 2 illustrated in FIG. 5 and a spatial synthesis method for spatially synthesizing beams. In order to achieve narrower beams, the wavelength synthesis method for focusing beams on the same optical axis is more advantageous than the spatial synthesis method. As illustrated in FIG. 5, the laser light beam having wavelength λ₁₁ and the laser light beam having wavelength λ_{1N} in semiconductor laser devicelaser device la emit light beams having different wavelengths because of different optical path lengths and different incident angles on diffraction grating 95. Also in semiconductor laser devicelaser device lb disposed at a different position from semiconductor laser devicelaser device la, beams having different wavelengths are emitted because optical path lengths and incident angles on diffraction grating 95 are different from those of semiconductor laser devicelaser device la. In order to increase beam output power by synthesizing a plurality of laser beams by the wavelength synthesis method, as described above, laser beams having a large number of wavelengths are required.

In semiconductor laser devicelaser devices la and lb according to the present exemplary embodiment, the reflectivity of end surface protective film 1F can be reduced to less than or equal to 1% in a wide wavelength range including the wavelengths of a plurality of laser beams. Therefore, it is not necessary to change the configuration at each luminous point of end surface protective film 1F of each semiconductor laser devicelaser device. Furthermore, the configurations of end surface protective films of semiconductor laser devicelaser devices 1a and 1b can also be standardized. Therefore, the configuration of semiconductor laser appatatus 2 can be simplified. Accordingly, a manufacturing process of semiconductor laser appatatus 2 can be simplified, so that the manufacturing of the semiconductor laser device can be stabilized, and the cost of the semiconductor laser device can be reduced. Furthermore, end surface protective film 1F according to the present exemplary embodiment includes first dielectric layer 10 disposed between second dielectric layer 20 and front end surface 50F, so that destruction of front end surface 50F can be reduced even when each semiconductor laser devicelaser device is operated at high output power for a long time. Therefore, a semiconductor laser device with high output power and high reliability can be achieved.

In addition, each of semiconductor laser devicelaser devices la and lb is a laser array, which has a plurality of luminous points each emitting a laser beam.

As a result, a small laser light source capable of emitting a plurality of laser beams can be achieved. A small semiconductor laser device can be achieved by using semiconductor laser devicelaser devices la and lb in semiconductor laser appatatus 2 of an external resonator type that performs wavelength synthesis.

Although semiconductor laser appatatus 2 includes two semiconductor laser devices la and lb, the number of semiconductor laser devices included in semiconductor laser appatatus 2 is not limited thereto, and may be one or three or more. In addition, each semiconductor laser device of semiconductor laser appatatus 2 has a plurality of luminous points, but each semiconductor laser device may have a single luminous point.

### Second Exemplary Embodiment

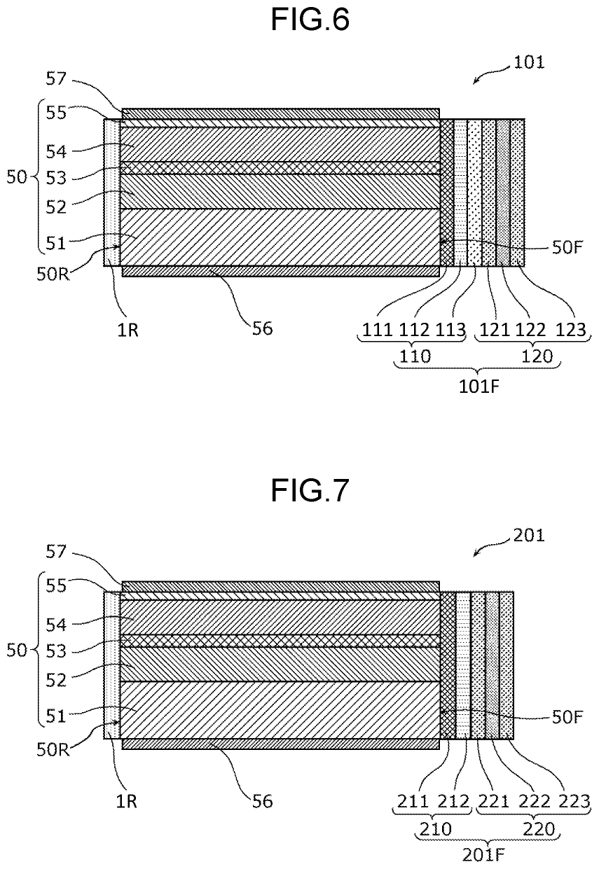

A semiconductor laser device according to a second exemplary embodiment will be described. A semiconductor laser device according to the present exemplary embodiment is different from semiconductor laser device 1 according to the first exemplary embodiment mainly in the configuration of the first dielectric layer. Hereinafter, the semiconductor laser device according to the present exemplary embodiment will be described with reference to FIG. 6, centering on differences from semiconductor laser device 1 according to the first exemplary embodiment.

FIG. 6 is a schematic cross-sectional view illustrating a configuration of semiconductor laser device 101 according to the present exemplary embodiment. FIG. 6 illustrates a cross section along a stacking direction of semiconductor stack body 50 included in semiconductor laser device 101 and a resonance direction of a laser beam.

As illustrated in FIG. 6, semiconductor laser device 101 according to the present exemplary embodiment includes semiconductor stack body 50, end surface protective films 101F and 1R, first electrode 56, and second electrode 57.

End surface protective film 101F according to the present exemplary embodiment includes first dielectric layer 110 and second dielectric layer 120.

First dielectric layer 110 according to the present exemplary embodiment includes a plurality of dielectric films. As illustrated in FIG. 6, first dielectric layer 110 includes first protective layer 111, second protective layer 112, and third protective layer 113.

First protective layer 111 is a dielectric film directly connected to front end surface 50F of semiconductor stack body 50. First protective layer 111 may include a dielectric film including at least one of a nitride film and an oxynitride film. In the present exemplary embodiment, first protective layer 111 includes an AlON film. More specifically, first protective layer 111 is a single-layer film including an AlON film having a thickness of about 20 nm. Note that the configuration of first protective layer 111 is not limited thereto. First protective layer 111 may be another oxynitride film such as SiON, or a nitride film such as an AlN film or a SiN film.

Second protective layer 112 is a dielectric film stacked on first protective layer 111. In the present exemplary embodiment, second protective layer 112 is a single-layer film including an Al₂O₃ film having a thickness of about 10 nm. Note that the configuration of second protective layer 112 is not limited thereto. Second protective layer 112 may be another dielectric film such as SiO₂.

Third protective layer 113 is a dielectric film stacked on second protective layer 112. Third protective layer 113 may include a dielectric film including at least one of a nitride film and an oxynitride film. In the present exemplary embodiment, third protective layer 113 is a single-layer film including an AlN film having a thickness of about 15 nm.

Note that the configuration of third protective layer 113 is not limited thereto. Third protective layer 113 may be another nitride film such as SiN, or an oxynitride film such as an AlON film or a SiON film.

As illustrated in FIG. 6, second dielectric layer 120 includes first layer 121, second layer 122, and third layer 123. First layer 121 according to the present exemplary embodiment is a single-layer film including a SiO₂ film having a thickness of about 100 nm. Second layer 122 according to the present exemplary embodiment is a single-layer film including a Ta₂O₅ film having a thickness of about 50 nm. Third layer 123 according to the present exemplary embodiment has the same configuration as third layer 23 according to the first exemplary embodiment.

Note that the configuration of second dielectric layer 120 is not limited thereto. Each of first layer 121 and third layer 123 has only to be a dielectric film having a lower refractive index than that of second layer 122, and may be another dielectric film such as an Al₂O₃film. In addition, second layer 122 has only to be a dielectric film having a higher refractive index than those of first layer 121 and third layer 123, and may be a SiN film, a

SiON film, a TiO₂ film, a Nb₂O₅ film, a HfO₂ film, an AlN film, an AlON film, or the like.

Semiconductor laser device 101 having the configuration as described above also exerts effects similar to those of semiconductor laser device 1 according to the first exemplary embodiment.

End surface protective film 101F according to the present exemplary embodiment includes at least two layers of dielectric films including at least one of a nitride film and an oxynitride film. More specifically, first dielectric layer 110 of end surface protective film 101F includes at least two layers of dielectric films including at least one of a nitride film and an oxynitride film. As a result, oxygen diffusion in the direction from front end surface 50F to semiconductor stack body 50 can be reduced more than in end surface protective film 1F according to the first exemplary embodiment. Therefore, front end surface 50F of semiconductor stack body 50 can be further suppressed from being deteriorated. Therefore, semiconductor laser device 101 capable of being operated for a longer period of time can be achieved.

### Third Exemplary Embodiment

A semiconductor laser device according to a third exemplary embodiment will be described. A semiconductor laser device according to the present embodiment is different from semiconductor laser device 101 according to the second exemplary embodiment in that a second dielectric layer of an end surface protective film includes a dielectric film including at least one of a nitride film and an oxynitride film. Hereinafter, the semiconductor laser device according to the present exemplary embodiment will be described with reference to FIG. 7, centering on differences from semiconductor laser device 101 according to the second exemplary embodiment.

FIG. 7 is a schematic cross-sectional view illustrating a configuration of semiconductor laser device 201 according to the present exemplary embodiment. FIG. 7 illustrates a cross section along a stacking direction of semiconductor stack body 50 included in semiconductor laser device 201 and a resonance direction of a laser beam.

As illustrated in FIG. 7, semiconductor laser device 201 according to the present exemplary embodiment includes semiconductor stack body 50, end surface protective films 201F and 1R, first electrode 56, and second electrode 57.

End surface protective film 201F according to the present exemplary embodiment includes first dielectric layer 210 and second dielectric layer 220.

First dielectric layer 210 according to the present exemplary embodiment includes a plurality of dielectric films. As illustrated in FIG. 7, first dielectric layer 210 includes first protective layer 211 and second protective layer 212.

First protective layer 211 is a dielectric film directly connected to front end surface 50F of semiconductor stack body 50. First protective layer 211 includes a dielectric film including at least one of a nitride film and an oxynitride film. In the present exemplary embodiment, first protective layer 211 includes an AlON film. More specifically, first protective layer 211 is a single-layer film including an AlON film having a thickness of about 20 nm. Note that the configuration of first protective layer 211 is not limited thereto.

First protective layer 211 may be another oxynitride film such as SiON, or a nitride film such as an AlN film or a SiN film.

Second protective layer 212 is a dielectric film stacked on first protective layer 211. In the present exemplary embodiment, second protective layer 212 is a single-layer film including an Al₂O₃ film having a thickness of about 10 nm. Note that the configuration of second protective layer 212 is not limited thereto. Second protective layer 212 may be another dielectric film such as SiO₂.

As illustrated in FIG. 7, second dielectric layer 220 includes first layer 221, second layer 222, and third layer 223. First layer 221 according to the present exemplary embodiment is a single-layer film including a SiO₂ film having a thickness of about 100 nm. Second layer 222 according to the present exemplary embodiment is a single-layer film including an AlN film having a thickness of about 30 nm. Third layer 223 according to the present exemplary embodiment has the same configuration as third layer 23 according to the first exemplary embodiment.

Note that the configuration of second dielectric layer 220 is not limited thereto.

Each of first layer 221 and third layer 223 has only to be a dielectric film having a lower refractive index than that of second layer 222, and may be another dielectric film such as an Al₂O₃film. Second layer 222 has only to be a nitride film or an oxynitride film having a refractive index higher than those of first layer 221 and third layer 223, and may be a SiN film, a SiON film, an AlON film, or the like.

Semiconductor laser device 201 having the configuration as described above also exerts effects similar to those of semiconductor laser device 1 according to the first exemplary embodiment.

End surface protective film 201F according to the present exemplary embodiment includes at least two layers of dielectric films including at least one of a nitride film and an oxynitride film. More specifically, in the present exemplary embodiment, each of first dielectric layer 210 and second dielectric layer 220 includes a dielectric film including at least one of a nitride film and an oxynitride film. As a result, oxygen diffusion from end surface protective film 101F to semiconductor stack body 50 can be reduced more than in end surface protective film 1F according to the first exemplary embodiment. Therefore, front end surface 50F of semiconductor stack body 50 can be further suppressed from being deteriorated. Therefore, semiconductor laser device 201 capable of being operated for a longer period of time can be achieved.

(Modifications and Others)

Although the semiconductor laser device according to the present disclosure has been described above based on each of the exemplary embodiments, the present disclosure is not limited to the each of the exemplary embodiments.

For example, first dielectric layer 10 is an AlN film in the first exemplary embodiment, but the configuration of first dielectric layer 10 is not limited thereto. First dielectric layer 10 may include, for example, at least one of a SiN film, an AlN film, a SiON film, an AlON film, an Al₂O₃ film, and a SiO₂ film.

In addition, each of the first dielectric layer, the first layer, the second layer, and the third layer may include a plurality of layers containing different materials. When the first dielectric layer is a single-layer film, a nitride film or an oxynitride film may be used as the first dielectric layer in order to protect the end surface of the semiconductor stack body. Specifically, an AlN film, an AlON film, a SiN film, a SiON film, or the like may be used as the first dielectric layer.

In each of the exemplary embodiments, an example has been described in which the semiconductor stack body is formed of a gallium nitride-based material and the end surface protective film has a low reflectivity near the wavelength band of 400 nm, but the configuration of the end surface protective film is not limited thereto. For example, the semiconductor stack body may be formed of an AlGaInP-based material, and the end surface protective film may have a low reflectivity in a red wavelength band (a band ranging from 600 nm to 700 nm inclusive). Alternatively, the semiconductor stack body may be formed of a gallium arsenide-based material, and the end surface protective film may have a low reflectivity in an infrared wavelength band (a band ranging from 750 nm to 1100 nm inclusive).

In addition, each of the end surface protective films may be formed by using a sputtering apparatus, a vapor deposition apparatus, or the like other than the solid-source ECR sputtering plasma deposition apparatus, or may be formed by using: an ablation deposition apparatus using pulse laser deposition (PLD), atomic layer deposition (ALD), or the like; an epitaxial growth apparatus using MOCVD or the like; or the like.

In addition, diffraction grating 95 of a transmission type is used as the wavelength dispersion element in semiconductor laser appatatus 2, but the wavelength dispersion element is not limited thereto. As the wavelength dispersion element, for example, a prism, a diffraction grating of a reflection type, or the like may be used.

The present disclosure also includes a mode obtained by making various modifications conceivable by those skilled in the art to each of the exemplary embodiments, and a mode achieved by arbitrarily combining components and functions in each of the exemplary embodiments without departing from the gist of the present disclosure.

### INDUSTRIAL APPLICABILITY

The semiconductor laser device of the present disclosure can be used for light sources of, for example: industrial laser equipment such as industrial lighting, facility lighting, in-vehicle headlamps, and laser processing machines; and image display devices such as laser displays and projectors, which particularly require watt-class high output power.

### REFERENCE MARKS IN THE DRAWINGS

1, 1a, 1b, 101, 201: semiconductor laser device
1F, 1R, 101F, 201F: end surface protective film
2: semiconductor laser device
10, 110, 210: first dielectric layer
20, 120, 220: second dielectric layer
21, 121, 221: first layer
22, 122, 222: second layer
23, 123, 223: third layer
50: semiconductor stack body
50F: front end surface
50R: rear end surface
51: substrate
52: first semiconductor layer
53: active layer
54: second semiconductor layer
55: contact layer
56: first electrode
57: second electrode
91a, 91b: optical lens
95: diffraction grating
97: partially reflective mirror
111, 211: first protective layer
112, 212: second protective layer
113: third protective layer

1. A semiconductor laser device that emits a laser beam, the semiconductor laser device comprising:
a semiconductor stack body having a front end surface and a rear end surface; and
an end surface protective film disposed on the front end surface of the semiconductor stack body, wherein
the end surface protective film includes a first dielectric layer disposed on the front end surface, and a second dielectric layer stacked outside the first dielectric layer, the second dielectric layer includes a first layer stacked on the first dielectric layer, a second layer stacked on the first layer, and a third layer stacked on the second layer, for wavelength λ, of the laser beam, refractive index n2 of the second layer is higher than each of refractive index n1 of the first layer and refractive index n3 of the third layer, and a film thickness of the second layer ranges from λ/(8n2) to 3λ/(4n2) inclusive.

2. The semiconductor laser device according to claim 1, wherein the first dielectric layer includes at least one layer of a dielectric film including at least one of a nitride film and an oxynitride film.

3. The semiconductor laser device according to claim 1, wherein the end surface protective film includes at least two layers of dielectric films including at least one of a nitride film and an oxynitride film.

4. The semiconductor laser device according to claim 1, wherein the first dielectric layer includes at least one of a SiN film, an AlN film, a SiON film, an AlON film, an Al2O3 film, and a SiO2 film.

5. The semiconductor laser device according to claim 1, wherein each of the first layer and the third layer includes at least one of a SiO₂ film and an Al₂O₃film.

6. The semiconductor laser device according to claim 1, wherein the second layer includes at least one of an AlN film, an AlON film, a TiO2 film, a Nb2O5 film, a ZrO2 film, a Ta2O5 film, and a HfO2 film.

7. The semiconductor laser device according to claim 1, wherein a reflectivity of the end surface protective film is less than or equal to 1.0% in a wavelength range, more than or equal to 50 nm, including the wavelength of the laser beam.

8. The semiconductor laser device according to claim 7, wherein the reflectivity of the end surface protective film is less than or equal to 0.5% in the wavelength range, more than or equal to 50 nm, including the wavelength of the laser beam.

9. The semiconductor laser device according to claim 1, wherein the semiconductor stack body is formed of a gallium nitride-based material.

10. The semiconductor laser device according to claim 1, wherein the semiconductor stack body is formed of a gallium arsenide-based material.

11. The semiconductor laser device according to claim 1, the semiconductor laser device comprising a plurality of luminous points, wherein each of the plurality of luminous points emits the laser beam.

12. The semiconductor laser device according to claim 1, wherein the second layer includes at least one of a SlN film and a SiON film.
